(19) United States
(12) Patent Application Publication
(10) Pub. No.: US 2026/0242949 A1
(43) Pub. Date: Aug. 20, 2026

(54) DEPOSITION MATERIAL FOR METALLOID NITRIDE FILM, METHOD OF FORMING METALLOID NITRIDE FILM, AND SEMICONDUCTOR SUBSTRATE AND SEMICONDUCTOR DEVICE FABRICATED USING THE SAME

(71) Applicant: SOULBRAIN CO., LTD., Gyeonggi-do (KR)

(72) Inventors: Seung Hyun LEE, Gyeonggi-do (KR); Jae Sun JUNG, Gyeonggi-do (KR); ChangBong YEON, Gyeonggi-do (KR)

(21) Appl. No.: 19/161,485

(22) PCT Filed: Apr. 26, 2024
(86) PCT No.: PCT/KR2024/005719

§ 371 Date: Sep. 2, 2025

(30) Foreign Application Priority Data
Apr. 27, 2023 (KR) 10-2023-0055217
Apr. 26, 2024 (KR) 10-2024-0056169

(51) Int. Cl. C23C 16/455; C01B 21/068; C23C 16/34; H10D 64/60

(52) U.S. Cl. CPC C23C 16/45553; C01B 21/068; C23C 16/345; H10D 64/60

(57) ABSTRACT

The present invention relates to a deposition material for metalloid nitride films, a method of forming a metalloid nitride film, and a semiconductor substrate and semiconductor device fabricated using the same. According to the present invention, by sequentially or simultaneously injecting a low-temperature deposition material into a metalloid precursor compound (halogen-free precursor) that does not include a halogen as a ligand, a site exchange between the ligand of the halogen-free precursor and the low-temperature deposition material occurs, and after adsorption on a substrate, the reactivity with a subsequently injected reactant in a deposition process is improved, thereby enhancing the thin film growth greatly improving the density and refractive index of a deposition film. Therefore, the present invention has an effect of providing a low-temperature deposition material for metalloid nitride films, a method of forming a metalloid nitride film, a semiconductor substrate and semiconductor device fabricated using the same.

### TECHNICAL FIELD

The present invention relates to a deposition material for metalloid nitride films, a method of forming a metalloid nitride film, and a semiconductor substrate and semiconductor device fabricated using the same. More particularly, according to the present invention, by sequentially or simultaneously injecting a low-temperature deposition material into a metalloid precursor compound (halogen-free precursor) that does not include a halogen as a ligand, a site exchange between the ligand of the halogen-free precursor and the low-temperature deposition material occurs, and after adsorption on a substrate, the reactivity with a subsequently injected reactant in a deposition process is improved, thereby enhancing the thin film growth rate and greatly improving the density and refractive index of a deposition film.

### BACKGROUND ART

An ideal atomic layer deposition (ALD) process is based on self-limiting reactions, in which the ligand of a precursor adsorbed on a substrate hinder the adsorption of the subsequently introduced precursor.

However, in actual processes, the precursor may be subjected to thermal budget, resulting in partial thermal decomposition in which the ligand dissociates from a central metal. This process exhibits characteristics of chemical vapor deposition (CVD). As this behavior becomes more pronounced, step coverage, the density of the deposition film, and thickness uniformity may decrease. In addition, when the dissociated ligand species are prone to adsorbing onto the surface or readily form fluorides or chlorides, the dissociated ligand species may remain in a deposited thin film as impurities (See J. Phys. Chem. B. 13491-8, “Surface chemistry in the atomic layer deposition of TiN films from TiCl₄ and ammonia” (2006)).

Factors such as the density and thickness uniformity of the deposition film influence chemical properties, and by-products derived from the leaving group may be absorbed, contaminating the deposition film or disrupting the crystal arrangement of the deposition film, potentially leading to further reduction in density.

Therefore, it is important to reduce the thermal budget experienced by the precursor to ensure that the desired process occurs within the atomic layer deposition (ALD) window.

In addition, a metalloid nitride film is a deposition film manufactured using representative metalloids such as silicon and germanium. For example, when depositing a silicon nitride thin film using a precursor such as Si₂Cl₆ or SiCl₂H₂, represented by chlorosilane, and a nitrogen-based reactant such as NH₃ or N₂H₂, thermal deposition is usually performed at a high temperature of 600° C. or higher to form a silicon nitride thin film (SiNₓ, where x is an integer from 0.8 to 1.2).

However, due to the aforementioned issues such as thermal budget, applying such high-temperature processes poses limitations.

To address this, plasma-assisted deposition processes at 400° C. have been reported. Nevertheless, silicon nitride films formed under low-temperature conditions tend to lack sufficient density, resulting in poor corrosion resistance, and ultimately, limitations in forming reliable structures for semiconductor device integration.

As an alternative, low-temperature silicon precursors such as bis(tertiarybutylamino) silane (BTBAS), tris(dimethylamino) silane (TDMAS), diisopropylaminosilane (DIPAS), bis-diethylaminosilane (BDEAS), and diiodosilane (DIS) have been utilized. However, silicon nitride films formed from these precursors often exhibit low density and low refractive index, which results in insufficient chemical durability.

Therefore, there is a growing need to develop a deposition film fabrication method in which a precursor adsorbed on a substrate through a self-limiting reaction undergoes ligand exchange with a second ligand of higher reactivity, followed by reaction with a reactant to enable the formation of a complex-structured deposition film. Such a method may improve the thickness uniformity and thin film growth rate, significantly reduce impurities, and greatly enhance the density and refractive index of a deposition film. In addition, there is a demand for the development of semiconductor substrates and semiconductor devices fabricated therefrom.

### RELATED ART DOCUMENTS

### Patent Documents

KR 2017-0089422 A

### DISCLOSURE

### Technical Problem

Therefore, the present invention has been made in view of the above problems, and it is one object of the present invention to provide a deposition material for metalloid nitride films, a method of forming a metalloid nitride film, and a semiconductor substrate and semiconductor device fabricated using the same. According to the present invention, by changing the ligand of a metalloid precursor compound by providing a compound having a predetermined structure as a second ligand before, during, or after precursor injection, the thin film growth rate and the thickness uniformity, density, and refractive index of a deposition film are greatly improved.

The above and other objects can be accomplished by the present invention described below.

### Technical Solution

In accordance with one aspect of the present invention, provided is a deposition material for metalloid nitride films, including an alkyl-free halide for substituting some or all of ligands of a group 14 metalloid precursor compound.

Halogens constituting the alkyl-free halide may include one or more selected from iodine and bromine.

The group 14 metalloid may be selected from one or more of silicon (Si), germanium (Ge), and tin (Sn).

The alkyl-free halide may be alkyl-free iodine, hydrogen iodide, hydrogen a material containing iodine ions, or a material containing iodine radicals.

In accordance with another aspect of the present invention, provided is a method of forming a metalloid nitride film, including replacing some or all of the ligands of the metalloid precursor compound by using some or all of the deposition material for metalloid nitride films on a substrate.

The metalloid precursor compound may be a precursor compound having a group 14 metalloid as A central metal.

The group 14 metalloid may include one or more selected from silicon (Si), germanium (Ge), and tin (Sn).

The ligand (L) may be -guanidiate, -amidinate, triazenide, -iPr, -tBu, -Cp, -Ph, —OR1, —OH, —H, or —NR2R3. Here, R1, R2, and R3 may independently be —CH₃, —CH₂CH₃, -iPr, -tBu, or —H.

The deposition may be atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low-pressure chemical vapor deposition (LPCVD).

In accordance with still another aspect of the present invention, provided is a semiconductor substrate including the metalloid nitride film described above on a substrate, wherein, when a precursor adsorption state before ligand exchange is represented as substrate-M-Ln (n is an integer from 1 to 3, M is Si, Ge, or Sn, and L is a halogen-free ligand), the metalloid nitride film has a precursor adsorption state after ligand exchange represented as substrate-M-LnXm (when L is a halogen-free ligand, X is Br or I, n is an integer from 1 to 3, and m is an integer from 1 to 3, n+m=3 is satisfied).

In accordance with still another aspect of the present invention, provided is a semiconductor substrate including the metalloid nitride film described above on a substrate, wherein, when a precursor before ligand exchange migrating onto the substrate is represented as M-Ln (n is an integer from 1 to 4, M is Si, Ge, or Sn, and L is a halogen-free ligand), the metalloid nitride film has a precursor state after ligand exchange represented as M-LnXm (when L is a halogen-free ligand, X is Br or I, n is an integer from 1 to 3, and m is an integer from 1 to 4, n+m=4 is satisfied).

The ligand (L) may be -guanidiate, -amidinate, -triazenide, -iPr, -tBu, -Cp, -Ph, —OR1, —OH, —H, or —NR2R3. Here, R1, R2, and R3 may independently be —CH₃, —CH₂CH₃, -iPr, -tBu, or —H, and the change in the precursor state before and after ligand exchange may be formed by a migration process onto the substrate and a reaction between alkyl-free halides for substituting ligands of a group 14 metalloid precursor with halogens of a deposition material on the substrate.

The semiconductor substrate may have a multilayer structure of two or more layers.

The metalloid nitride film may have a thin film growth rate of 0.09 Å/cycle or more as calculated by dividing a thickness measured by an ellipsometer by the number of deposition cycles.

The metalloid nitride film may have a refractive index (@350 nm wavelength) of 2 or less as measured using an ellipsometer.

In accordance with yet another aspect of the present invention, provided is a semiconductor device including the semiconductor substrate described above.

### Advantageous Effects

According to the present invention, by replacing some or all of the precursor ligands adsorbed on a substrate with halogens, the thin film growth rate can be improved and the thickness uniformity and density of a deposition film can be appropriately increased. Accordingly, an activation effect that enhances deposition film productivity can be obtained.

In addition, the density and refractive index can be improved during deposition film formation. Accordingly, the effect of providing etching corrosion resistance necessary for forming the structure of a semiconductor device can be obtained.

In addition, the thickness uniformity of the deposition film can be improved even with a complex structure. In addition, the present invention has the effect of providing a method for forming a deposition film and a semiconductor substrate and semiconductor device fabricated using the same.

### DESCRIPTION OF DRAWINGS

FIG. 1 is a diagram comparing the thin film growth rates of three deposition films (Examples 1 to 3) according to deposition temperature, using a deposition material for metalloid nitride films according to the present invention.

FIG. 2 is a diagram confirming the linearity of cycles by increasing the deposition cycles from 100 to 1000 in Example 2 using a deposition material for metalloid nitride films according to the present invention.

FIG. 3 is a diagram comparing the refractive index (@350 nm wavelength) of the deposition film from Example 1 using a deposition material for metalloid nitride films according to the present invention, with the refractive indices (@350 nm wavelength) of deposition films obtained from Comparative Examples 4, 7, and 8.

FIG. 4 is a diagram comparing the XRR (X-ray reflectometer, X-ray diffraction) film density of deposition films from Examples 1 to 3, which used a deposition material for metalloid nitride films according to the present invention, with the XRR film density of deposition films from Comparative Examples 4 to 6, which did not use such material.

### BEST MODEL

Hereinafter, a deposition material for metalloid nitride films according to the present invention, a method of forming a metalloid nitride film, and a semiconductor substrate and semiconductor device fabricated using the same will be described in detail.

In the present disclosure, the metalloids used refer to Group 14 elements represented by silicon (Si) and germanium (Ge), unless otherwise specified.

The present inventors confirmed that, by providing a predetermined compound (deposition material for metalloid nitride films) capable of replacing the halogen-free ligands of a metalloid precursor compound used to form a deposition film on the surface of a substrate loaded inside a chamber, the thin film growth rate was improved, the thickness uniformity of the deposition film was secured, the density and refractive index of the deposition film were greatly improved, and H, C, N, and Cl remaining as process byproducts were reduced. Based on these results, the present inventors conducted d further research on the deposition material for metalloid nitride films and completed the present invention.

Hereinafter, a deposition material for metalloid nitride films, and a semiconductor substrate and semiconductor device including a deposition film manufactured using the same will be described in detail.

### Deposition Material for Metalloid Nitride Films

The deposition material for metalloid nitride films, in the present invention, may be a deposition additive compound used to more effectively form a deposition film on the surface of a substrate loaded inside a chamber, and may be a predetermined compound capable of replacing ligands to be dissociated from a precursor.

For example, the metalloid precursor compound may be a compound in which ligands are bonded to a group 14 metalloid, and the ligands bonded to a central metal thereof may be partially or entirely exchanged with the ligands of the deposition material for metalloid nitride films.

When the deposition material for metalloid nitride films used in the present invention is an alkyl-free halide, the deposition material may appropriately function to substitute the halogen-free ligand of the precursor through site exchange

Unless otherwise specified, the term “alkyl-free” refers not only to the absence of alkyl groups but also to the exclusion of alkene and alkyne groups.

The halogens constituting the alkyl-free halide may be selected from one or more of iodine and bromine.

The deposition material for metalloid nitride films may be a compound having a purity of preferably 99.99% or more, 99.999% or more, or 99.9999% or 99.99999% or more, For reference, when a compound having a purity of less than 99% is used, impurities may remain in a deposition film or cause side reactions with precursors or reactants. Accordingly, it is desirable to use a material having a purity of 99% or more.

The deposition material for metalloid nitride films may have preferably a density of 1.0 to 4.0 g/cm³ or 2.0 to 3.4 g/cm³ and a vapor pressure of 1 atm at 180 to 240 K. Within this range, step coverage and the thickness uniformity and film quality of a deposition film may be greatly improved.

As the deposition material for metalloid nitride films, an alkyl-free halide may form an intermediate that provides a deposition film having a structure in which a reactant-derived species is bonded to the group 14 metalloid.

Here, the “intermediate” may refer to a state in which the ligand of the metalloid precursor compound is replaced by a compound of a predetermined structure acting as a second ligand.

Here, the reactant may be a gaseous compound including H₂O, H₂O₂, O₂, O₃, O radicals, D₂, H₂, H radicals, NH₃, NO₂, N₂O, N₂, N radicals, H₂S, or S. Here, D represents deuterium.

The alkyl-free halide may include one or more selected from alkyl-free iodine, hydrogen iodide, hydrogen bromide, iodine ions, or iodine radicals. In this case, by suppressing side reactions and controlling the deposition film growth rate, process byproducts within the deposition film may be reduced, preventing corrosion and deterioration and enhancing the crystallinity of the deposition film. Furthermore, a stoichiometric composition ratio may be achieved during metal oxide film formation. Furthermore, when forming a deposition film on a substrate with a complex structure, step coverage and the thickness uniformity of the deposition film may be significantly improved.

As a specific example, the deposition material for metalloid nitride films may be is 3 N to 15 N hydrogen iodide, a gas mixture containing 0.01 to 99.99% by weight of 3 N to 15 N hydrogen iodide and a residual amount (amount that makes a total amount 100% by weight) of an inert gas, or an aqueous solution mixture containing 0.5 to 70% by weight of 3 N to 15 N hydrogen iodide and a residual amount (amount that makes a total amount 100% by weight) of water. Here, when the inert gas is nitrogen, helium, or argon with a purity of 4 N to 9 N, process byproducts may be significantly reduced, step coverage may be improved, and the density of the deposition film may be greatly improved. Here, N represents normal concentration.

Preferably, the deposition material for metalloid nitride films may be is 3 N to 7 N hydrogen iodide, a gas mixture containing 1 to 99% by weight of 5 N to 6 N hydrogen iodide and a residual amount (amount that makes a total amount 100% by weight) of an inert gas, or an aqueous solution mixture containing 0.5 to 70% by weight of 5 N to 6 N hydrogen iodide and a residual amount (amount that makes a total amount 100% by weight) of water. Here, the inert gas may be nitrogen, helium, or argon having a purity of 4 N to 9 N. In this case, by forming a substitution region that does not remain in the deposition film during the formation of the deposition film, a relatively coarse deposition film may be formed while suppressing side reactions. Furthermore, by controlling the growth rate of the deposition film, process byproducts within the deposition film may be reduced, corrosion or deterioration may be mitigated, and the crystallinity of the deposition film may be improved. Furthermore, even when forming a deposition film on a substrate with a complex structure, step coverage and the thickness uniformity of the deposition film may be significantly improved.

The present invention may include a step of vaporizing and injecting the deposition material for metalloid nitride films or the metalloid precursor compound, and then performing plasma post-processing before or after deposition. In this case, the growth rate of the deposition film may be improved, and process byproducts may be reduced.

The deposition may be atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low-pressure chemical vapor deposition (LPCVD).

### Metalloid Precursor Compound

In the present invention, the metalloid precursor compound used to form a deposition film is a molecule having a group 14 metalloid as a central metal atom (M) and having at least one ligand selected from C, N, O, and H. When the metalloid precursor compound is a precursor having a vapor pressure of 1 mTorr to 100 Torr at 25° C., the effect of filling a leaving site may be maximized by using the deposition material for metalloid nitride films described below.

For example, a compound having a structure in which one or more ligands (L) are bonded to a group 14 metalloid may be used as the metalloid precursor compound.

The ligand (L) may be -guanidiate, -amidinate, -triazenide, -iPr, -tBu, -Cp, -Ph, —OR1, —OH, —H, or —NR2R3. Here, R1, R2, and R3 may independently be —CH₃, —CH₂CH₃, -iPr, -tBu, or —H. In this case, the change in the precursor state before and after ligand exchange may be formed by a migration process onto the substrate and the reaction between alkyl-free halides for substituting the ligands of a group 14 metalloid precursor with the halogens of a deposition material on the substrate.

As a specific example, silicon may be used as a compound represented by Chemical Formula 1-1 or 1-2.

In Chemical Formula 1-1 below, silicon may be replaced with other group 14 elements, such as germanium (Ge). In this case, process byproducts may be significantly reduced, step coverage may be improved, and the density of the deposition film may be excellent.

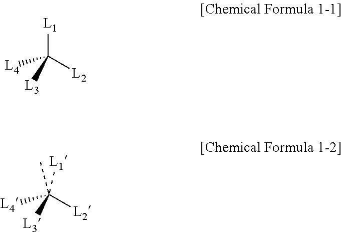

In the case of Chemical Formula 1-1 or 1-2, process byproducts may be significantly reduced, step coverage may be improved, and the density of the deposition film may be greatly improved.

In Chemical Formula 1-1, L1, L2, L3, and L4 may be the same or different.

For example, in Chemical Formula 1-1, L₁ may be -guanidiate, -amidinate, -triazenide, -iPr, -tBu, -Cp, -Ph, or —OR1, and L₂, L₃, and L₄ may each independently be —H, —CH₃, —CH₂CH₃, —OH, —NR2R3. Here, R1, R2, and R3 may independently be —CH₃, —CH₂CH₃, -iPr, or -tBu.

As another example, in Chemical Formula 1-1, L₁ and L₂ may each independently be -iPr, -tBu, -Cp, -Ph, or —OR1, and L₃ and L₄ may each independently be —H, —CH₃, —CH₂CH₃, —OH, or —NR2R3. Here, R1, R2, and R3 may independently be —CH₃, —CH₂CH₃, -iPr, or -tBu.

As another example, in Chemical Formula 1-1, L₁, L₂, and L₃ may each independently be -iPr, -tBu, -Cp, -Ph, or —OR1, and L₄ may be —H, —CH₃, —CH₂CH₃, —OH, —NR2R3. Here, R1, R2, and R3 may independently be —CH₃, —CH₂CH₃, -iPr, or -tBu.

As another example, in Chemical Formula 1-1, L_{1′}, L_{2′}, L_{3′}, and L_{4′} may each independently be -iPr, -tBu, -Cp, -Ph, or —OR1, and R1 may be —H, —CH₃, —CH₂CH₃, -iPr, or -tBu.

In Chemical Formula 1-1, the ligands may form symmetric or asymmetric structures.

In Chemical Formula 1-2, L1′, L2′, L3′, and L4′ may be the same or different.

For example, in Chemical Formula 1-2, L_{1′} may be -guanidiate, -amidinate, -triazenide, -iPr, -tBu, -Cp, -Ph, or —OR1, and L2, L3′, and L4 may each independently be —H, —CH₃, —CH₂CH₃, —OH, and —NR2R3. Here, R1, R2, and R3 may independently be —CH₃, —CH₂CH₃, -iPr, or -tBu.

As another example, in Chemical Formula 1-2, L_{1′} and L_{2′} may each independently be -iPr, -tBu, -Cp, -Ph, or —OR1, and L_{3′} and L_{4′} may each independently be —H, —CH₃, —CH₂CH₃, —OH, or —NR2R3. Here, R1, R2, and R3 may independently be —CH₃, —CH₂CH₃, -iPr, or -tBu.

As another example, in Chemical Formula 1-2, L_{1′}, L_{2′}, and L_{3′} may each independently be -iPr, -tBu, -Cp, -Ph, or —OR1, and L4 may be —H, —CH₃, —CH₂CH₃, —OH, or —NR2R3. Here, R1, R2, and R3 may independently be —CH₃, —CH₂CH₃, -iPr, or -tBu.

As another example, in Chemical Formula 1-2, L_{1′}, L_{2′}, L_{3′}, and L_{4′} may each independently be -iPr, -tBu, -Cp, -Ph, or —OR1, and R1 may be —H, —CH₃, —CH₂CH₃, -iPr, or -tBu.

In the present disclosure, unless otherwise stated, Pr refers to a propyl group, Bu refers to a butyl group, and Ph refers to a phenyl group.

For example, the structure represented by Chemical Formula 1-1 or 1-2 may be diphenyl silane (DPS), diiodo silane (DIS), hexachloro disilane (HCDS), dichloro silane (DCS), or the like.

In the present invention, the metalloid precursor compound may be mixed with a non-polar solvent and introduced into the chamber. In this case, the viscosity or vapor pressure of the metalloid precursor compound may be easily controlled.

The non-polar solvent may include preferably one or selected from the group consisting of alkanes and cycloalkanes. In this case, an organic solvent with low reactivity and easy moisture management may be included. In addition, step coverage may be improved even when deposition temperature increases during deposition film formation.

As a preferred example, the non-polar solvent may include a C1 to C10 alkane or a C3 to C10 cycloalkane, preferably a C3 to C10 cycloalkane. In this case, reactivity may be low and moisture management may be easy.

In the present disclosure, C1, C3, and the like indicate the number of carbon atoms.

The cycloalkane may preferably include C3 to C10 monocycloalkanes, and among the monocycloalkanes, cyclopentane is liquid at room temperature and has the highest vapor pressure, so cyclopentane is preferable in the vapor deposition process, but the present invention is not limited thereto.

For example, the non-polar solvent may have a solubility (25° C.) of 200 mg/L or less, preferably 50 to 400 mg/L, more preferably 135 to 175 mg/L in water. Within this range, the reactivity toward the metalloid precursor compound may be reduced, and moisture may be easily managed.

In the present disclosure, solubility may be measured without any particular limitation by a measurement method or standard commonly used in the technical field to which the present invention pertains. For example, solubility may be measured by the HPLC method using a saturated solution.

Based on a total weight of the metalloid precursor compound and the non-polar solvent, the non-polar solvent may be included in an amount of 5 to 95% by weight, more preferably 10 to 90% by weight, still more preferably 40 to 90% by weight, most preferably 70 to 90% by weight.

When the content of the non-polar solvent exceeds the above range, impurities may be generated, which may increase impurities within a deposition film. When the content of the organic solvent is less than the range, the effect of improving step coverage due to solvent addition and the effect of reducing impurities may be reduced.

In addition, the metalloid precursor compound may be injected into the deposition chamber simultaneously with the aforementioned low-temperature deposition material, or the metalloid precursor compound may be pre-injected into the deposition chamber and then the low-temperature deposition material may be post-injected.

### Metalloid Nitride Film

A deposition film obtained using the deposition material for metalloid nitride films described above is included.

When a precursor adsorption state before ligand exchange is represented as substrate-M-Ln (n is an integer from 1 to 3, M is Si, Ge, or Sn, and L is a halogen-free ligand), the metalloid nitride film has a precursor adsorption state after ligand exchange represented as substrate-M-LnXm (when L is a halogen-free ligand, X is Br or I, n is an integer from 1 to 3, and m is an integer from 1 to 3, n+m=3 is satisfied), or when a precursor before ligand exchange migrating onto the substrate is represented as M-Ln (n is an integer from 1 to 4, M is Si, Ge, or Sn, and L is a halogen-free ligand), the metalloid nitride film has a precursor state after ligand exchange represented as M-LnXm (when L is a halogen-free ligand, X is Br or I, n is an integer from 1 to 3, and m is an integer from 1 to 4, n+m=4 is satisfied).

The ligand (L) may be -guanidiate, -amidinate, -triazenide, -iPr, -tBu, -Cp, -Ph, —OR1, —OH, —H, or —NR2R3. Here, R1, R2, and R3 may independently be —CH₃, —CH₂CH₃, -iPr, -tBu, or —H. In this case, the change in the precursor state before and after ligand exchange may be formed by a migration process onto the substrate and the reaction between alkyl-free halides for substituting the ligands of a group 14 metalloid precursor with the halogens of a deposition material on the substrate.

For example, the metalloid nitride film may include a structure represented by Chemical Formula 2 below.

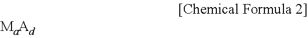

(In Chemical Formula 2, M is a group 14 metalloid, A includes one or more of N and S, a is an integer greater than or equal to 1, and d is 0.8 to 2.2.)

The deposition film may be a nitride film alone, or may include a nitride film and a sulfide film or chalcogenide. In this case, the purpose of the present invention may be achieved.

The deposition film may include the aforementioned film composition alone or in a selective area, but is not limited thereto, and may also include SiH, SiOH, and the like.

In addition to the commonly used diffusion barrier, the deposition film may be used in semiconductor devices as an etch stop film, electrode film, dielectric film, gate insulating film, block oxide film or charge trap.

For example, the deposition film may be manufactured in a variety of ways, including the following method.

As a first step, a group 14 metalloid and a metalloid precursor compound containing a ligand may be injected onto a substrate loaded in a chamber.

For example, the ligand may be L₁, L₂, L₃, L₄, L_{1′}, L_{2′}, L_{3′}, or L_{4′} represented by Chemical Formulas 1-1 and 1-2. Here, repeated description is omitted.

In the present disclosure, the method of delivering the metalloid precursor compound to the deposition chamber may include a vapor flow control (VFC) method in which the volatilized gas is transferred using a mass flow controller (MFC), a mass flow controller (MFC) method such as a liquid mass flow controller (LMFC) method, or a liquid delivery system (LDS).

At this time, as a carrier gas or dilution gas for moving the metalloid precursor compound onto the substrate, one or more mixed gases selected from the group consisting of argon (Ar), nitrogen (N₂), and helium (He) may be used, but this is not limited thereto.

In the present disclosure, an inert gas, preferably a carrier gas or dilution gas may be used as a purge gas.

The chamber may be an atomic layer deposition (ALD) chamber, a plasma-enhanced atomic layer deposition (PEALD) chamber, a chemical vapor deposition (CVD) chamber, a plasma-enhanced chemical vapor deposition (PECVD) chamber, a metal-organic chemical vapor deposition (MOCVD) chamber, or a low-pressure chemical vapor deposition (LPCVD) chamber.

After loading the substrate into the chamber, purging pretreatment may be performed.

In the present disclosure, purging may be performed at preferably 1,000 to 50,000 sccm (Standard Cubic Centimeter per Minute), more preferably 2,000 to 30,000 sccm, still more preferably 2,500 to 15,000 sccm. Within this range, the deposition film growth rate per cycle may be appropriately controlled, and deposition may be performed as an atomic monolayer or close to the atomic monolayer, which may provide advantageous advantages in terms of film quality.

The substrate loaded into the chamber may include a semiconductor substrate, such as a silicon substrate or a silicon oxide substrate.

The substrate may further have a conductive layer or an insulating layer formed on the upper portion thereof.

The substrate may be maintained at 50 to 500° C., or 80 to 500° C., within the chamber.

For example, the substrate may be heated to 50 to 500° C., as a specific example, 80 to 500° C., 100 to 800° C., or 200 to 500° C. The metalloid precursor compound and a deposition material for metalloid nitride films described later may be injected onto the substrate in an unheated or heated state, or may be injected unheated and then heated during the deposition process, depending on the deposition efficiency. For example, the metalloid precursor compound and the deposition material may be injected onto the substrate heated to 300 to 600° C. for 1 to 30 seconds.

As the input amount of metalloid precursor compound injected into the chamber (mg/cycle), the input amount (mg/cycle) ratio of the deposition material for metalloid nitride films used in the second step to be described later to the metalloid precursor compound into the chamber may be, for example, 1:1 to 1:20, preferably 1:1 to 1:15, more preferably 1:1 to 1:10. Within this range, step coverage may be improved, and process by-products may be greatly reduced.

The first step may include one or more purging steps using an inert gas. The inert gas may be the carrier gas or dilution gas described above.

In the step of purging the unadsorbed metalloid precursor compound, the amount of purge gas introduced into the chamber is not particularly limited as long as the amount is sufficient to remove the unadsorbed metalloid precursor compound. For example, the amount may be 10 to 100,000 times, preferably 50 to 50,000 times, and more preferably 100 to 10,000 times the volume of the metalloid precursor compound introduced into the chamber. Within this range, the unabsorbed metalloid precursor compound may be sufficiently removed to form a uniform deposition film and prevent deterioration of film quality. Here, the input amounts of the purge gas and metalloid precursor compound are each based on one cycle, and the volume of the metalloid precursor compound refers to the volume of vaporized metalloid precursor compound vapor.

In the present disclosure, purging may be performed at preferably 1,000 to 50,000 sccm (Standard Cubic Centimeter per Minute), more preferably 2,000 to 30,000 sccm, still more preferably 2,500 to 15,000 sccm. Within this range, the deposition film growth rate per cycle may be appropriately controlled, and deposition may be performed as an atomic monolayer or close to the atomic monolayer, which may provide advantageous advantages in terms of film quality.

In the second step, an alkyl-free halide is injected as a low-temperature deposition material to change the ligand-leaving site into a halogen. This effectively releases the precursor ligand adsorbed on the substrate, improving the reaction rate and appropriately reducing the deposition film growth rate. Thus, even when forming a deposition film on a substrate with a complex structure, step coverage and the thickness uniformity of the deposition film may be significantly improved.

For example, the halogen may be selected from one or more of iodine and bromine, and it is preferable to use iodine.

The feeding time (sec) per cycle of the deposition material for metalloid nitride films onto the surface of the substrate may be preferably 0.001 to 30 seconds, more preferably 0.02 to 30 seconds, still more preferably 0.04 to 30 seconds, still more preferably 0.05 to 30 seconds. Within this range, the deposition film growth rate may be high, and step coverage and cost efficiency may be excellent.

In the present disclosure, the feeding time of the deposition material for metalloid nitride films is based on a flow rate of 1 to 500 sccm in a chamber volume of 15 to 20 L, and more specifically, on a flow rate of 10 to 200 sccm in a chamber volume of 18 L.

In the present disclosure, the method of delivering the deposition material for metalloid nitride films to the deposition chamber may be, for example, a method of transporting volatilized gas (vapor flow control; VFC) using a mass flow controller (MFC) method.

The second step may include one or more purging steps using an inert gas. In the present disclosure, the purge gas may be, for example, a carrier gas or a dilution gas.

In the present disclosure, purging may be performed at preferably 1,000 to 50,000 sccm (Standard Cubic Centimeter per Minute), more preferably 2,000 to 30,000 sccm, still more preferably 2,500 to 15,000 sccm. Within this range, the deposition film growth rate per cycle may be appropriately controlled, and deposition may be performed as an atomic monolayer or close to the atomic monolayer, which may provide advantageous advantages in terms of film quality.

The amount of purge gas introduced into the chamber in the step of purging the unadsorbed deposition material for metalloid nitride films is not particularly limited as long as the amount is an amount sufficient to remove the unadsorbed deposition material for metalloid nitride films, but for example, the amount may be 10 to 100,000 times, preferably 50 to 50,000 times, more preferably 100 to 10,000 times. Within this range, the unadsorbed deposition material for metalloid nitride films may be sufficiently removed to form a uniform deposition film and prevent deterioration of film quality. Here, the input amounts of the purge gas and deposition material for metalloid nitride films are each based on one cycle, and the volume of the deposition material for metalloid nitride films refers to the volume of vaporized deposition material for metalloid nitride films.

As a specific example, when the deposition material for metalloid nitride films is injected at a flow rate of 100 sccm and an injection time of 0.5 sec (based on 1 cycle), and purge gas is injected at a flow rate of 3000 sccm and an injection time of 5 sec (based on 1 cycle) in the step of purging the unadsorbed deposition material for metalloid nitride films, the injection amount of the purge gas is 300 times the injection amount of the deposition material for metalloid nitride films.

When necessary, the first and second steps may be combined or performed in reverse order.

That is, the metalloid precursor compound and the low-temperature deposition material may be simultaneously injected into the deposition chamber and then purged. This allows for the replacement of all or part of the precursor ligand with the low-temperature deposition material, enhancing substrate adsorption.

In addition, the low-temperature deposition material may be sequentially injected into the deposition chamber, purged, and then the metalloid precursor compound may be injected into the deposition chamber and then purged. This allows for the replacement of all or part of the low-temperature deposition material with the precursor ligand, enhancing substrate adsorption.

The chemical structure in which the ligand of the metalloid precursor compound is replaced may be formed through a “pre-injection process” in which the alkyl-free halogen compound is introduced prior to the precursor injection process (sequential injection), a “co-injection process” in which the alkyl-free halogen compound and the precursor are introduced simultaneously (co-injection), or a “post-injection process” in which the alkyl-free halogen compound is introduced after the precursor injection process. As a result, this may be formed through the reaction of part or all of the ligands of the metalloid precursor compound implanted on the substrate with an alkyl-free halide containing halogen.

The ligand of the metalloid precursor compound implanted on the substrate and substituted with an alkyl-free halogen ligand is removed by reacting with hydrogen (H) derived from the reactant, and thus the group 14 metalloid adsorbed on the substrate may form a thin film by combining with nitrogen (N) derived from the reactant.

Next, as a third step, a reactant may be introduced onto the substrate to form a deposition film derived from a group 14 metalloid.

The reactant may be, for example, a gaseous compound including H₂O, H₂O₂, O₂, O₃, O radicals, D₂, H₂, H radicals, NH₃, N₂H₂, N₂O, N₂, N radicals, H₂S, or S.

The intermediate of the deposition film may include a structure in which a group 14 metalloid is bonded with both a reactant-derived material and a halogen.

The deposition film may include a structure in which the group 14 metalloid is bonded with a reactant-derived material.

For example, the method of forming a deposition film may be performed at a deposition temperature of 50 to 800° C., preferably 100 to 700° C., more preferably 200 to 650° C., still more preferably 220 to 500° C., still more preferably 220 to 450° C. Within this range, the process characteristics may be implemented, and a deposition film having excellent film quality may be grown.

For example, the method of forming a deposition film may be performed under a deposition pressure of 0.01 to 20 Torr, preferably 0.1 to 20 Torr, more preferably 0.1 to 10 Torr. Within this range, a deposition film having a uniform thickness may be obtained.

In the present disclosure, the deposition temperature and the deposition pressure may be measured as temperature and chamber, or as pressure formed within the deposition temperature and pressure applied to the substrate within the deposition chamber.

The second step may further include a step of increasing the temperature inside the chamber to a deposition temperature before introducing the deposition material for metalloid nitride films into the chamber; and/or a step of performing purging by injecting an inert gas into the chamber before introducing the deposition material for metalloid nitride films into the chamber.

The third step may include a purging step using an inert gas.

In the purging step performed immediately after supplying the reaction gas, the amount of purge gas introduced into the chamber may be, for example, 10 to 10,000 times, preferably 50 to 50,000 times, more preferably 100 to 10,000 times the volume of the reaction gas introduced into the chamber. Within this range, the desired objectives may be effectively achieved. Here, the injection amounts of both the purge gas and the reaction gas are based on a single cycle.

In the present disclosure, purging may be performed at preferably 1,000 to 50,000 sccm (standard cubic centimeter per minute), more preferably 2,000 to 30,000 sccm, still more preferably 2,500 to 15,000 sccm. Within this range, the deposition film growth rate per cycle may be appropriately controlled. In addition, since deposition is performed as an atomic mono-layer or nearly an atomic mono-layer, the film quality may be improved.

Depending on the need, the method of forming a deposition film may perform the unit cycle 1 to 99, 999 times, preferably 10 to 10,000 times, more preferably 50 to 5,000 times, still more preferably 100 to 2,000 times. Within this range, the desired thickness of the deposition film may be obtained, and the purpose of the present invention may be achieved.

As a specific example, according to the method of forming a deposition film, to deposit a deposition film on a substrate positioned in the chamber, the above-described deposition material for metalloid nitride films and a metalloid precursor compound or a mixture thereof with a non-polar solvent are prepared.

Next, the prepared metalloid precursor compound or a mixture thereof with a non-polar solvent is injected into a vaporizer, changed into a vapor phase, transferred to a deposition chamber, and adsorbed onto a substrate. The ligand of the metalloid precursor compound is replaced by the pre-injected deposition material for metalloid nitride films, and the unadsorbed metalloid precursor compound is purged.

Next, the prepared deposition material for metalloid nitride films is injected into a vaporizer, changed into a vapor phase, transferred to the deposition chamber, adsorbed onto the substrate, and purged to remove unadsorbed deposition material for metalloid nitride films.

In the present disclosure, the method of transferring the deposition material for metalloid nitride films and the metalloid precursor compound to the deposition chamber may include a vapor flow control (VFC) method in which the volatilized gas is transferred using a mass flow controller (MFC) or a liquid delivery system (LDS) using a liquid mass flow controller (LMFC) method.

At this time, as a transport gas or dilution gas for moving the deposition material for metalloid nitride films and the metalloid precursor compound onto a substrate, one or more mixed gases selected from the group consisting of argon (Ar), nitrogen (N₂), and helium (He) may be used, but this is not limited thereto.

In the present disclosure, for example, an inert gas, preferably a carrier gas or a dilution gas may be used as a purge gas.

Next, a reactant is supplied.

The reactant is not particularly limited as long as the reactant is a reaction gas commonly used in the technical field to which the present invention belongs, and may preferably include a nitriding agent. The nitriding agent reacts with the metalloid precursor compound adsorbed on the substrate to form a nitride film.

Preferably, the nitriding agent may be nitrogen gas (N₂), hydrazine gas (N₂H₄), or a mixture of nitrogen gas and hydrogen gas.

Next, the unreacted residual reaction gas is purged using an inert gas. Accordingly, not only the excess reaction gas but also the generated byproducts may be removed.

For example, according to the method of forming a deposition film, a step of adsorbing a metalloid precursor compound onto a substrate, a step of purging an unadsorbed metalloid precursor compound, a step of supplying a deposition material for metalloid nitride films onto the substrate, a step of purging an unadsorbed deposition material for metalloid nitride films, a step of supplying a reaction gas, and a step of purging a residual reaction gas may be set as a unit cycle, and the unit cycle may be repeated to form a deposition film of a desired thickness.

As another example, according to the method of forming a deposition film, a step of transferring a metalloid precursor compound and a low-temperature deposition material to a substrate and reacting the metalloid precursor compound and the low-temperature deposition material to replace ligands, a step of adsorbing the replaced precursor compound onto the substrate, a step of purging the unadsorbed metalloid precursor compound, the replaced precursor compound, and the unreacted low-temperature deposition material, a step of supplying a reaction gas, and a step of purging the residual reaction gas may be set as a unit cycle, and the unit cycle may be repeated to form a deposition film of a desired thickness.

For example, the unit cycle may be repeated 1 to 99, 999 times, preferably 10 to 1,000 times, more preferably 50 to 5,000 times, still more preferably 100 to 2,000 times. Within this range, the desired deposition film thin film properties may be well expressed.

When the injection time and purge time of the metalloid precursor compound in the first step are a and b, respectively, the injection time and purge time of the alkyl-free halide in the second step are c and d, respectively, and the injection time and purge time of the reactant in the third step are e and f, respectively, 0.1≤a≤30, a≤b≤3a, 0.1≤c≤30, c≤d≤4c, 2≤e≤60, and e≤f≤3e may be satisfied simultaneously.

When the injection and purging of the metalloid precursor compound and the alkyl-free halide, and the injection and purging of the reactant are considered as one cycle, the following four conditions may all be satisfied: 1) the metalloid nitride film has a deposition thickness of 500 Å or less as measured by an ellipsometer, 2) the thin film growth rate is 0.09 Å/cycle or more, 3) the density of the deposition film is 2 g/cm³ or more, and 4) the refractive index (@350 nm wavelength) of the deposition film is 2 or more.

The metalloid nitride film may have a deposition thickness of 500 Å or less, or 2 to 300 Å, more preferably 5 to 250 Å as measured using an ellipsometer.

The deposition film may have a density of 2 to 5.5 g/cm³, or 2 to 5 g/cm³.

The metalloid nitride film may have a refractive index (@350 nm wavelength) of 2 or less, or 1 to 2 as measured using an ellipsometer.

For example, the method of manufacturing a deposition film may be performed using a deposition film manufacturing device including an ALD chamber, a first vaporizer for vaporizing a deposition material for metalloid nitride films, a first transport means for transporting the vaporized deposition material for metalloid nitride films into the ALD chamber, a second vaporizer for vaporizing a deposition film precursor, and a second transport means for transporting the vaporized deposition film precursor into the ALD chamber. Here, the vaporizer and transport means are not particularly limited as long as the vaporizer and transport means are vaporizers and transport means commonly used in the technical field to which the present invention belongs, and the vaporizer may be omitted when a gas mixture or vapor pressure at room temperature is 0.1 Torr or higher.

### Semiconductor Substrate

In addition, the present invention provides a semiconductor substrate. The semiconductor substrate is fabricated using the method of forming a deposition film of the present invention, or includes the deposition film. In this case, the step coverage and thickness uniformity of the deposition film may be excellent, and the density of the deposition film may be excellent.

As described above, the change in the adsorption state of the metalloid precursor before and after ligand exchange may be formed by the reaction between halogens on the substrate and a alkyl-free halide containing halogens to fill the ligand leaving sites of the group 14 metalloid precursor compound and the aforementioned metalloid precursor compound.

For example, the semiconductor substrate may include a metalloid nitride film formed through a process in which the ligand bonded to the group 14 metalloid is first substituted with a halogen atom (Br or I) that constitutes the alkyl-free halide, and then the vacant position of the halogen atom (Br or I) is further replaced with nitrogen (N).

For example, when a precursor adsorption state before ligand exchange on the substrate is represented as substrate-M-Ln (n is an integer from 1 to 3, M is Si, Ge, or Sn, and L is a halogen-free ligand), the semiconductor substrate may have a precursor adsorption state after ligand exchange represented as substrate-M-LnXm (when L is a halogen-free ligand, X is Br or I, n is an integer from 1 to 3, and m is an integer from 1 to 3, n+m=3 is satisfied).

As another example, when a precursor before ligand exchange migrating onto the substrate is M-Ln (n is an integer from 1 to 4, M is Si, Ge, or Sn, and L is a halogen-free ligand), the semiconductor substrate may have a precursor state after ligand exchange represented as M-LnXm (when L is a halogen-free ligand, X is Br or I, n is an integer from 1 to 3, and m is an integer from 1 to 4, n+m=4 is satisfied).

For example, the metalloid nitride film may have a multilayer structure of two or more layers, a multilayer structure of three or more layers, or a multilayer structure with two or three layers, as needed. The two-layer multilayer film may, as a specific example, have a lower layer-middle layer structure, and the three-layer multilayer film may, as a specific example, have a lower layer-middle layer-upper layer structure.

The middle layer may be, as a specific example, a TiN electrode for DRAM or a barrier film for NAND.

For example, the lower layer is a metal film, nitride film, or oxide film of different composition from the metalloid nitride film, and may include one or more selected from the group consisting of Si, SiO₂, MgO, Al₂O₃, Cao, ZrSiO₄, ZrO₂, HfSiO₄, Y₂O₃, HfO₂, LaLuO₂, Si₃N₄, SrO, La₂O₃, Ta₂O₅, Bao, and TiO₂.

For example, the upper layer may be a metal film, nitride film, or oxide film of a different composition from the metalloid nitride film, and may include one or more selected from the group consisting of Si, SiO₂, TiN, TiSiN, W, Mo, and MON.

### Semiconductor Device

According to the present invention, the present invention may provide a semiconductor device including the semiconductor substrate described above.

For example, the semiconductor device may be a low resistive metal gate interconnect, a high aspect ratio 3D metal-insulator-metal (MIM) capacitor, a DRAM trench capacitor, a 3D gate-all-around (GAA), or a 3D NAND flash memory.

Hereinafter, preferred examples and drawings are presented to help understand the present invention, but the following examples and drawings are only illustrative of the present invention, and it is obvious to those skilled in the art that various changes and modifications are possible within the scope and technical idea of the present invention. Such changes and modifications fall within the scope of the appended patent claims.

### EXAMPLES

As metalloid precursor compounds, diphenyl silane (DPS), diiodo silane (DIS), hexachloro disilane (HCDS), and dichloro silane (DCS) were prepared, respectively.

As a deposition material for metalloid nitride films, 6N HI was prepared.

An ALD deposition process was performed using the metalloid precursor compound and the deposition material for metalloid nitride films, with the deposition process sequence according to the present invention as one cycle.

The specific experimental methods for Examples 1 to 6 and Comparative Examples 1 to 8 are as follows.

### Examples 1 to 3

The internal atmosphere of a deposition chamber was formed by injecting 3000 sccm of argon into a chamber through a mass flow controller (MFC) to achieve a working pressure of 1.2 Torr.

Next, a silicon wafer was placed on the heating block and the block was heated to reach the designated deposition temperature.

Next, the canister filled with the metalloid precursor, as shown in Table 1 below, was heated or cooled so that the vapor pressure was 0.01 to 10 Torr when the metalloid precursor was injected into the chamber, and 100 sccm of hydrogen iodide as a low-temperature deposition material was injected into the chamber for 1 to 30 seconds while the metalloid precursor was introduced into the chamber in a vapor state. Then, the metalloid precursor and the low-temperature deposition material were purged for twice the injection time.

Subsequently, ammonia was introduced into the chamber as a reactant at 500 sccm for 3 to 60 seconds using plasma at 100 W, followed by a purging step that lasted twice the ammonia injection time. Detailed experimental conditions are summarized in Table 1 below.

This process was repeated 200 to 400 times to form three types of self-limiting atomic layer deposition (ALD) films.

### Comparative Examples 1 to 3

The same process as in Examples 1 to 3 was performed except that no low-temperature deposition material was used.

### Examples 4 to 6

The internal atmosphere of the deposition chamber was created by injecting 3000 sccm of argon into the chamber using a mass flow controller (MFC) to achieve a working pressure of 1.2 Torr.

Then, the silicon wafer was placed on a heating block and the heating block was heated to the deposition temperature.

Next, the canister filled with the metalloid precursor, as shown in Table 1 below, was heated or cooled so that the vapor pressure was 0.01 to 10 Torr when the metalloid precursor was injected into the chamber, and the metalloid precursor in a vapor state was injected into the chamber for 1 to 30 seconds. Then, purging was performed for twice the time of metalloid precursor injection.

Next, the canister filled with the low-temperature deposition material was heated or cooled, and 100 sccm of hydrogen iodide was injected into the chamber for 1 to 30 seconds. Afterwards, purging was performed for twice the injection time of the low-temperature deposition material.

Subsequently, ammonia was introduced into the chamber as a reactant at 500 sccm for 3 to 60 seconds using plasma at 100 W, followed by a purging step that lasted twice the ammonia injection time. Detailed experimental conditions are summarized in Table 1 below.

This process was repeated 200 to 400 times to form three types of self-limiting atomic layer deposition (ALD) films.

### Comparative Examples 4 to 6

The same process as in Examples 4 to 6 was performed except that no low-temperature deposition material was used.

### Comparative Examples 7 and 8

The same process as in Comparative Example 4 was performed except that the metalloid precursor was replaced with the material shown in Table 1 below, and the deposition temperature was increased to 600° C.

### Test Examples

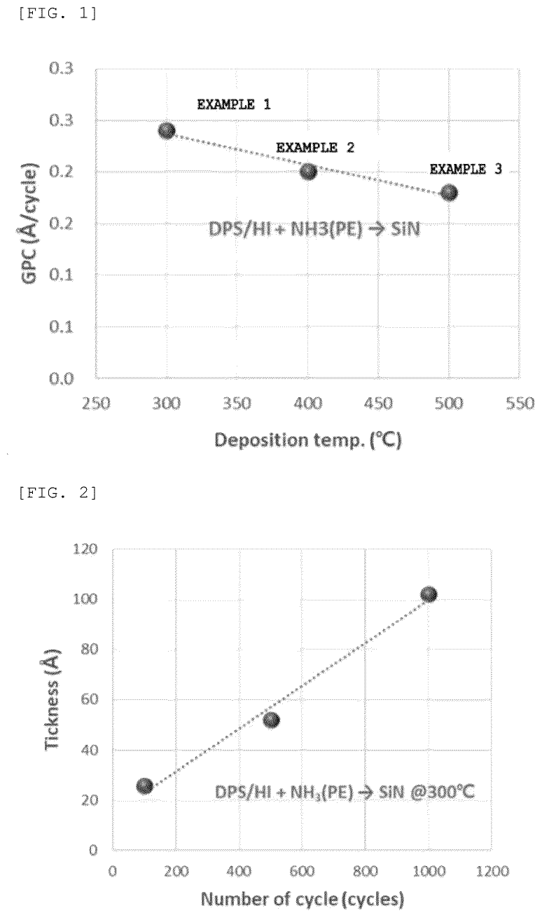

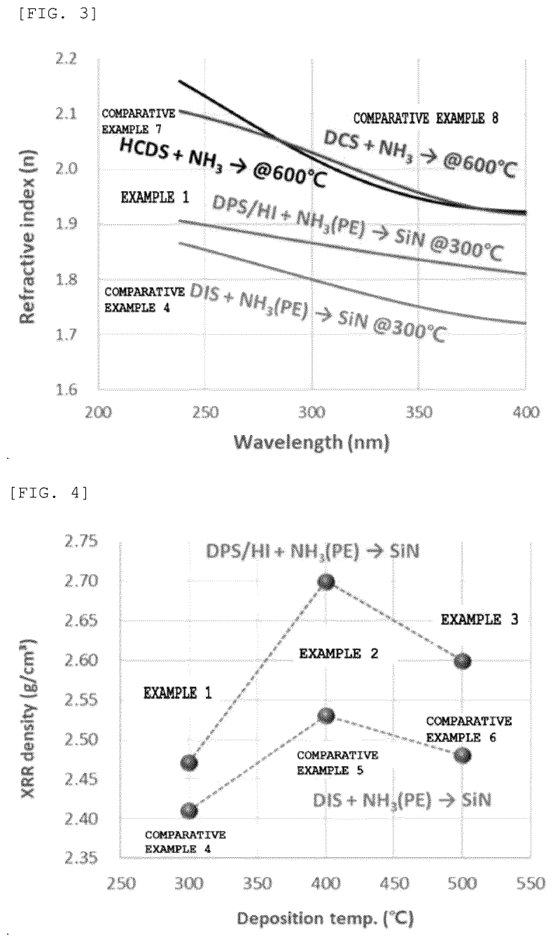

Thin film growth rate: The thickness of deposition films with thicknesses ranging from 1 to 30 nm was measured at room temperature under atmospheric pressure using an ellipsometer, and the thin film growth rate was calculated by dividing the thickness by the number of deposition cycles. The unit of the thin film growth rate is Å/cycle. The measurement results are shown in Table 1 and FIG. 2.
Cycle linearity: In Example 2, the number of deposition cycles was increased from 100 to 1000, and the thickness of the resulting film was measured. The results are presented in FIG. 2.
Refractive index: The refractive index (@350 nm wavelength) of the manufactured deposition films was measured using an ellipsometer. The results are provided in Table 1, FIG. 2, and FIG. 3.
Thin film density: The density of the manufactured deposition films was measured using an X-ray reflectometry (XRR) instrument. The results are presented in Table 1 and FIG. 4.

TABLE 1

| | | Low- | | | Deposition | Refractive | Thin film |
|---|---|---|---|---|---|---|---|
| | | temperature | | | rate | index | density |
| | Metalloid | deposition | | Deposition | (Å/cycle) | (λ = 350 nm) | (g/cm³) |
| Classification | precursor | material | Reactant | temperature | [FIG. 1] | [FIG. 3] | [FIG. 4] |
| Example 1 | DPS | HI (co- | NH₃ (PE | 300° C. | 0.24 | 1.83 | 2.47 |
| | | injection) | 100 W) | | | | |
| Example 2 | DPS | HI (co- | NH₃ (PE | 400° C. | 0.2 | — | 2.70 |
| | | injection) | 100 W) | | | | |
| Example 3 | DPS | HI (co- | NH₃ (PE | 500° C. | 0.18 | — | 2.60 |
| | | injection) | 100 W) | | | | |
| Example 4 | DPS | HI (post- | NH₃ (PE | 300° C. | 0.13 | — | — |
| | | injection) | 100 W) | | | | |
| Example 5 | DPS | HI (post- | NH₃ (PE | 300° C. | 0.1 | — | — |
| | | injection) | 100 W) | | | | |
| Example 6 | DPS | HI (post- | NH₃ (PE | 300° C. | 0.09 | — | — |
| | | injection) | 100 W) | | | | |
| Comparative | DPS | — | NH₃ (PE | 300° C. | N/A | — | — |
| Example 1 | | | 100 W) | | | | |
| Comparative | DPS | — | NH₃ (PE | 400° C. | N/A | — | — |
| Example 2 | | | 100 W) | | | | |
| Comparative | DPS | — | NH₃ (PE | 500° C. | N/A | — | — |
| Example 3 | | | 100 W) | | | | |
| Comparative | DIS | — | NH₃ (PE | 300° C. | 1.02 | 1.75 | 2.41 |
| Example 4 | | | 100 W) | | | | |
| Comparative | DIS | — | NH₃ (PE | 400° C. | 0.95 | — | 2.53 |
| Example 5 | | | 100 W) | | | | |
| Comparative | DIS | — | NH₃ (PE | 500° C. | 0.87 | — | 2.48 |
| Example 6 | | | 100 W) | | | | |
| Comparative | HCDS | — | NH₃ | 600° C. | 0.6 | 1.94 | — |
| Example 7 | | | | | | | |
| Comparative | DCS | — | NH₃ | 600° C. | 0.45 | 1.95 | — |
| Example 8 | | | | | | | |

As shown in Table 1, Examples 1 to 6 according to the present invention using a deposition material for metalloid nitride films different from a precursor ligand showed significantly improved thin film growth rate, refractive index, and thin film density compared to Comparative Examples 1 to 8, which did not use a low-temperature deposition material. In particular, in Comparative Examples 1 to 3, which

did not use the deposition material for metalloid nitride films according to the present invention, thin films were not grown. On the other hand, in Examples 1 to 3, which used the deposition material, a significantly reduced thin film growth rate was achieved, as confirmed in FIG. 1. For reference, FIG. 1 is a diagram comparing the thin film growth rates of three deposition films (Examples 1 to 3) according to deposition temperature, using a deposition material for metalloid nitride films according to the present invention.

As shown in FIG. 2, in the case of Example 2 using the deposition material for metalloid nitride films according to the present invention, the linearity of the cycles was confirmed by measuring the thickness of the thin film while increasing from 100 cycles to 1000 cycles.

In addition, in the case of Example 1 using the deposition material for metalloid nitride films according to the present invention, the refractive index value was higher than that of Comparative Examples 4, 7, and 8 that did not use the deposition material, as shown in FIG. 3. For reference, FIG. 3 is a diagram comparing the refractive index (@350 nm wavelength) of the deposition film from Example 1 using a deposition material for metalloid nitride films according to the present invention, with the refractive indices (@350 nm wavelength) of deposition films obtained from Comparative Examples 4, 7, and 8.

In addition, Examples 1 to 3 using the deposition material for metalloid nitride films according to the present invention showed a higher film density than Comparative Examples 4 to 6 that did not use the deposition material, as shown in FIG. 4. For reference, FIG. 4 is a diagram comparing the XRR (X-ray diffraction) film density of deposition films from Examples 1 to 3, which used a deposition material for metalloid nitride films according to the present invention, with the XRR (X-ray diffraction) film density of deposition films from Comparative Examples 4 to 6, which did not use such material.

Therefore, according to the present invention, by sequentially or simultaneously injecting the low-temperature deposition material into i the metalloid precursor compound (halogen-free precursor) that does not include a halogen as a ligand, a site exchange between the ligand of the halogen-free precursor and the low-temperature deposition material occurs, and after adsorption on the substrate, the reactivity with the subsequently injected reactant in the deposition process is improved, thereby enhancing the thin film growth rate and greatly improving the density and refractive index of a deposition film. Thus, it can be confirmed that the deposition film is formed uniformly even on a substrate with a complex pattern.

1. A deposition material for metalloid nitride films, comprising an alkyl-free halide for substituting some or all of ligands of a group 14 metalloid precursor compound.

2. The deposition material according to claim 1, wherein halogens constituting the alkyl-free halide comprise one or more selected from iodine and bromine.

3. The deposition material according to claim 1, wherein the group 14 metalloid is selected from one or more of silicon (Si), germanium (Ge), and tin (Sn).

4. The deposition material according to claim 1, wherein the alkyl-free halide is alkyl-free iodine, hydrogen iodide, hydrogen bromide, iodine ion, or iodine radical.

5. A method of forming a metalloid nitride film, comprising replacing some or all of the ligands of the metalloid precursor compound by using some or all of the deposition material for metalloid nitride films comprising the alkyl-free halide according to claim 1 on a substrate.

6. The method according to claim 5, wherein the metalloid precursor compound is a precursor compound centered on a group 14 metalloid, and the group 14 metalloid comprises one or more selected from silicon (Si), germanium (Ge), and tin (Sn).

7. The method according to claim 5, wherein the ligand (L) is-guanidiate, -amidinate, -triazenide, -iPr, -tBu, -Cp, -Ph, —OR1, —OH, —H, or —NR2R3,
wherein R1, R2, and R3 are independently —CH₃, —CH₂CH₃, -iPr, -tBu, or —H.

8. The method according to claim 5, wherein the deposition is atomic layer deposition (ALD), plasma-enhanced atomic layer deposition (PEALD), chemical vapor deposition (CVD), plasma-enhanced chemical vapor deposition (PECVD), metalorganic chemical vapor deposition (MOCVD), or low-pressure chemical vapor deposition (LPCVD).

9. A semiconductor substrate comprising the metalloid nitride film formed using the method according to claim 5 on a substrate,
wherein, when a precursor adsorption state before ligand exchange is represented as substrate-M-Ln (n is an integer from 1 to 3, Mis Si, Ge, or Sn, and L is a halogen-free ligand), the metalloid nitride film has a precursor adsorption state after ligand exchange represented as substrate-M-LnXm (when L is a halogen-free ligand, X is Br or I, n is an integer from 1 to 3, and m is an integer from 1 to 3, n+m=3 is satisfied).

10. A semiconductor substrate comprising the metalloid nitride film formed using the method according to claim 5 on a substrate,
wherein, when a precursor before ligand exchange migrating onto the substrate is represented as M-Ln (n is an integer from 1 to 4, Mis Si, Ge, or Sn, and L is a halogen-free ligand), the metalloid nitride film has a precursor state after ligand exchange represented as M-LnXm (when L is a halogen-free ligand, X is Br or I, n is an integer from 1 to 3, and m is an integer from 1 to 4, n+m=4 is satisfied),

11. The semiconductor substrate according to claim 9, wherein the ligand (L) is-guanidiate, -amidinate, -triazenide, -iPr, -tBu, -Cp, -Ph, —OR1, —OH, —H, or —NR2R3,
wherein R1, R2, and R3 are independently —CH₃, —CH₂CH₃, -iPr, -tBu, or —H, and the change in the precursor state before and after ligand exchange is formed by a migration process onto the substrate and a reaction between alkyl-free halides for substituting ligands of a group 14 metalloid precursor with halogens of a deposition material on the substrate.

12. The semiconductor substrate according to claim 9, wherein the semiconductor substrate has a multilayer structure of two or more layers.

13. The semiconductor substrate according to claim 9, wherein the metalloid nitride film has a thin film growth rate of 0.09 Å/cycle or more as calculated by dividing a thickness measured by an ellipsometer by the number of deposition cycles.

14. The semiconductor substrate according to claim 9, wherein the metalloid nitride film has a refractive index (@350 nm wavelength) of 2 or less as measured using an ellipsometer.

15. A semiconductor device comprising the semiconductor substrate according to claim 9.
